(19) United States
(12) Patent Application Publication
(10) Pub. No.: US 2026/0136963 A1
(43) Pub. Date: May 14, 2026

(54) SEMICONDUCTOR PACKAGE INCLUDING OPTICAL DEVICE PACKAGE

(71) Applicant: Samsung Electronics Co., Ltd., Suwon-si (KR)

(72) Inventors: Junghoon KANG, Suwon-si (KR); Hyeonjeong HWANG, Suwon-si (KR)

(73) Assignee: Samsung Electronics Co., Ltd., Suwon-si (KR)

(21) Appl. No.: 19/216,227

(22) Filed: May 22, 2025

(30) Foreign Application Priority Data
Nov. 14, 2024 (KR) 10-2024-0162254

(51) Int. Cl. H01L 23/498; G02B 6/12; H01L 23/31; H01L 25/16

(52) U.S. Cl. CPC H10W 70/635; G02B 6/12; H10W 74/111; H10W 90/00; G02B 2006/12038

(57) ABSTRACT

A semiconductor package includes an interposer structure including an interposer body, an interposer upper interconnect structure and an interposer lower interconnect structure, and an interposer through via, an electronic device on the interposer structure and electrically connected to the interposer upper interconnect structure, an electronic mold layer, an optical device package to be in contact with the electronic mold layer, the optical device package being electrically connected to the interposer upper interconnect structure. The optical device package includes a glass substrate on which a substrate optical waveguide is formed, a substrate redistribution structure, the substrate redistribution structure being electrically connected to the interposer upper interconnect structure, an optical device electrically connected to the substrate redistribution structure and including a device optical waveguide coupled to the substrate optical waveguide, an optical mold layer, and an optical connector structure optically connected to the substrate optical waveguide.

### CROSS-REFERENCE TO RELATED APPLICATION

This application is based on and claims priority under 35 U.S.C. § 119 to Korean Patent Application No. 10-2024-0162254, filed on Nov. 14, 2024, in the Korean Intellectual Property Office, the disclosure of which is incorporated by reference herein in its entirety.

### BACKGROUND

The inventive concepts relate to a semiconductor package, and more particularly, to a semiconductor package including an optical device package.

Electronic products are controlled by using various semiconductor packages. With the developments of bio health, artificial intelligence (AI), and autonomous robots, an optical backplane is being explored as a replacement for electrical backplane interfaces for data transmission. Thus, an optical device has been mounted on a semiconductor package, and the characteristics of the optical device, such as bandwidth density, energy efficiency, optical coupling loss, etc., may have (potentially significantly) increased importance.

### SUMMARY

The inventive concepts provide a semiconductor package including an optical device package which may increase bandwidth density and/or energy efficiency and/or reduce optical coupling loss.

According to an aspect of the inventive concepts, there is provided a semiconductor package including an interposer structure comprising an interposer body, an interposer upper interconnect structure above the interposer body an interposer lower interconnect structure below the interposer body, and an interposer through via in the interposer body, the interposer through via electrically connecting the interposer upper interconnect structure to the interposer lower interconnect structure; an electronic device on the interposer structure, the electronic device electrically connected to the interposer upper interconnect structure; an electronic mold layer on the electronic device and on the interposer structure; and an optical device package in contact with the electronic mold layer, on the interposer structure, facing a side of the electronic device, and electrically connected to the interposer upper interconnect structure, the optical device package comprising a glass substrate, the glass substrate including which a substrate optical waveguide, a substrate redistribution structure below the glass substrate, the substrate redistribution structure electrically connected to the interposer upper interconnect structure, an optical device on the glass substrate and electrically connected to the substrate redistribution structure, the optical device comprising a device optical waveguide coupled to the substrate optical waveguide, and an optical mold layer on the glass substrate and on the optical device; and an optical connector structure on a side of the glass substrate and optically connected to the substrate optical waveguide.

According to another aspect of the inventive concepts, there is provided a semiconductor package including an interposer structure comprising an interposer body, an interposer upper interconnect structure above the interposer body, an interposer lower interconnect structure below the interposer body, and an interposer through via in the interposer body, the interposer through via electrically connecting the interposer upper interconnect structure to the interposer lower interconnect structure; at least one electronic device on the interposer structure, the at least one electronic device electrically connected to the interposer upper interconnect structure; an electronic mold layer on the at least one electronic device and on the interposer structure; an optical device package in contact with the electronic mold layer, on the interposer structure, facing a side of the at least one electronic device, and electrically connected to the interposer upper interconnect structure, the optical device package comprises a glass substrate, a cavity lower than an upper surface of the glass substrate, a substrate optical waveguide on the upper surface of the glass substrate, an inner electronic device in the cavity, a substrate redistribution structure below the glass substrate and electrically connected to the interposer upper interconnect structure, an optical device on the inner electronic device, the optical device electrically connected to the inner electronic device and the substrate redistribution structure, and comprising a device optical waveguide coupled to the substrate optical waveguide, and an optical mold layer on the glass substrate, on the inner electronic device, and on the optical device; and an optical connector structure optically connected to the substrate optical waveguide on a side of the glass substrate.

According to another aspect of the inventive concepts, there is provided a semiconductor package including an interposer structure comprising an interposer body, an interposer upper interconnect structure above the interposer body, an interposer lower interconnect structure below the interposer body, and an interposer through via in the interposer body, the interposer through via connecting the interposer upper interconnect structure to the interposer lower interconnect structure; at least one bridge device in the interposer body, the at least one bridge device electrically connected to the interposer upper interconnect structure; at least one electronic device on the interposer structure, the at least one electronic device electrically connected to the interposer upper interconnect structure and the at least one bridge device; an electronic mold layer on the at least one electronic device and on the interposer structure; an optical device package in contact with the electronic mold layer, on the interposer structure, on a side of the at least one electronic device, and electrically connected to the at least one electronic device through the interposer upper interconnect structure and the at least one bridge device, the optical device package comprises a glass substrate, a cavity lower than an upper surface of the glass substrate, a substrate optical waveguide on the upper surface of the glass substrate, an inner electronic device in the cavity, a substrate redistribution structure below the glass substrate and electrically connected to the interposer upper interconnect structure, an optical device on the inner electronic device, the optical device electrically connected to the inner electronic device and the substrate redistribution structure, and comprising a device optical waveguide coupled to the substrate optical waveguide, and an optical mold layer on the glass substrate, the inner electronic device, and the optical device; and an optical connector structure optically connected to the substrate optical waveguide on a side of the glass substrate.

According to another aspect of the inventive concepts, there is provided a method of producing a semiconductor package, the method including patterning a glass substrate such that the patterned substrate includes a cavity, a protrusion portion defining the cavity, and a via hole in the cavity; forming substrate through via in the via hole; forming a substrate optical waveguide on the protrusion portion; mounting an optical device to the glass substrate such that the optical device is electrically connected to the substrate through via and optically connected to the substrate optical waveguide; forming a protective layer on a portion of the substrate optical waveguide exposed by the optical device; forming a mold material layer over the glass substrate, the protective layer, and the optical device; forming an optical mold layer by etching the mold material layer.

The forming the substrate optical waveguide may include applying a mask to a surface of the protrusion; exchanging, on a portion of the surface of the protrusion exposed by the mask, a portion of initials ion with a replacement ion using a first ion exchange; removing the mask; exchanging a portion of the replacement ions exchanged on the surface of the protrusion with the initial ions using a second ion exchange.

The method may further comprise attaching the glass substrate to an interposer substrate.

### BRIEF DESCRIPTION OF THE DRAWINGS

Embodiments will be more clearly understood from the following detailed description taken in conjunction with the accompanying drawings in which:

FIG. 1 is a cross-sectional view of a semiconductor package according to at least one example embodiment;

FIG. 2 is a cross-sectional view for describing an optical signal path and an electronic signal path of the semiconductor package of FIG. 1;

FIG. 3 is a cross-sectional view for describing an optical device package of the semiconductor package of FIG. 1;

FIGS. 4 to 10 are cross-sectional views for describing a method of manufacturing the optical device package of FIGS. 1 to 3;

FIGS. 11 to 18 are views for describing a method of manufacturing a substrate optical waveguide of the optical device package of FIGS. 1 to 3;

FIGS. 19 to 22 are cross-sectional views for describing a method of manufacturing the optical device package of FIGS. 1 to 3;

FIG. 23 is a view for describing an optical coupling relationship between an optical device package and an optical connector structure according to at least one example embodiment;

FIG. 24 is a view for describing an optical coupling relationship between an optical device package and an optical connector structure according to at least one example embodiment;

FIG. 25 is a cross-sectional view of a semiconductor package according to at least one example embodiment;

FIG. 26 is a cross-sectional view for describing an optical device package which may be included in a semiconductor package according to at least one example embodiment;

FIG. 27 is a cross-sectional view for describing an optical device package which may be included in a semiconductor package according to at least one example embodiment;

FIGS. 28A and 28B are cross-sectional views for describing an optical device which may be included in an optical device package according to at least one example embodiment;

FIGS. 29A and 29B are cross-sectional views for describing an electronic device which may be included in an optical device package according to at least one example embodiment;

FIG. 30 is a cross-sectional view for describing a coupling relationship between an electronic device and an optical device which may be included in an optical device package according to at least one example embodiment; and

FIG. 31 is a cross-sectional view for describing a coupling relationship between an electronic device and an optical device which may be included in an optical device package according to at least one example embodiment.

### DETAILED DESCRIPTION OF THE EMBODIMENTS

Hereinafter, embodiments will be described in detail by referring to the accompanying drawings, wherein like reference numerals refer to like elements throughout. In this regard, the present embodiments may have different forms and should not be construed as being limited to the descriptions set forth herein. The embodiments described hereinafter may be realized as any one of the embodiments, and the embodiments described hereinafter may be realized as a combination of one or more of the embodiments. Thus, the inventive concepts shall not be interpreted by being limited to one embodiment.

In this specification, singular forms of components may include a plurality of forms, unless clearly otherwise indicated in context. In this specification, drawings are illustrated in an exaggerated fashion to clearly describe the inventive concepts.

Spatially relative terms, such as above, below, etc. are represented herein based on the direction illustrated in the drawings and may be represented otherwise when the orientation of the corresponding object changes. In other words, such spatially relative terms are intended to encompass different orientations of the device in use or operation in addition to the orientation depicted in the figures, such that the device may be otherwise oriented (rotated 90 degrees or at other orientations) and the spatially relative terms used herein interpreted accordingly.

Additionally, when the terms “about” or “substantially” are used in this specification in connection with a numerical value and/or geometric term, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry. Further, whenever a range of values is enumerated, the range includes all values within the range, and may further include the boundaries of the range. Accordingly, a range of “X” to “Y” includes any value between X and Y, including X and Y, unless expressly indicated otherwise.

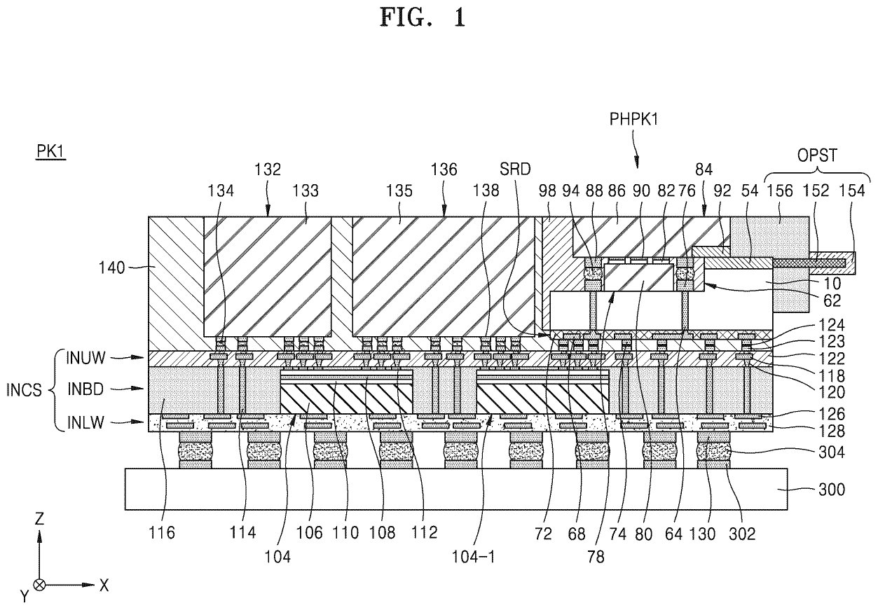

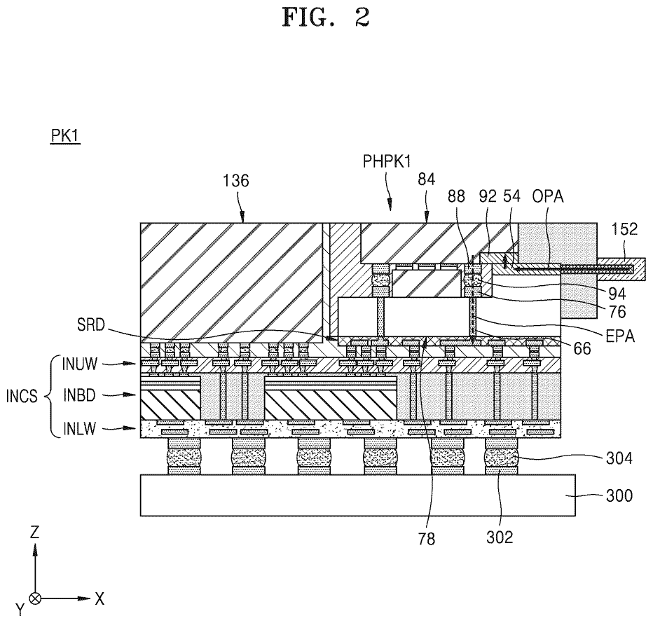

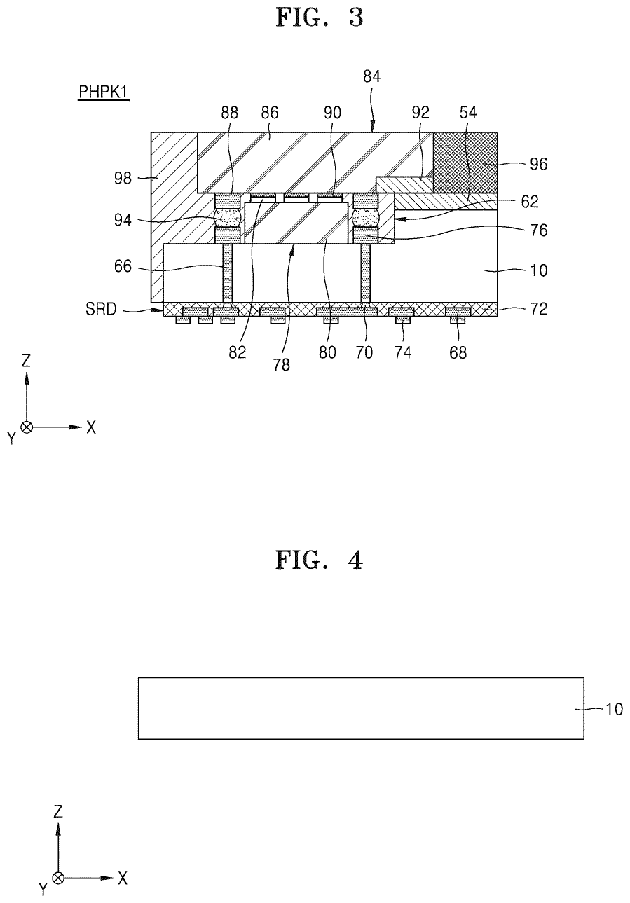

FIG. 1 is a cross-sectional view of a semiconductor package PK1 according to at least one example embodiment, FIG. 2 is a cross-sectional view for describing an optical signal path and an electronic signal path of the semiconductor package PK1 of FIG. 1, and FIG. 3 is a cross-sectional view for describing an optical device package PHPK1 of the semiconductor package PK1 of FIG. 1.

In detail, the semiconductor package PK1 may include a main substrate 300, an interposer structure INCS, bridge devices 104 and 104-1, electronic devices 132 and 136, an electronic mold layer 140, an optical device package PHPK1, and an optical connector structure OPST.

The main substrate 300 may include a printed circuit board (PCB). A main pad 302 may be arranged on the main substrate 300. The main pad 302 may include a conductive layer, for example, a metal layer. For example, in at least some example embodiments, the metal layer may be and/or include a copper layer. An external connection terminal 304 connected to an interposer lower pad 130 of the interposer structure INS may be located on the main pad 302. The external connection terminal 304 may include a solder ball.

The interposer structure INCS may include an interposer body INBD, an interposer upper interconnect structure INUW, an interposer lower interconnect structure INLW, and an interposer through via 114. The interposer body INBD may include an interposer molding layer 116. The interposer molding layer 116 may include, for example, a resin layer. For example, in at least some example embodiments, the resin layer of the interposer molding layer 116 may include epoxy.

The interposer upper interconnect structure INUW may be arranged above the interposer body INBD. The interposer lower interconnect structure INLW may be arranged below the interposer body INBD. The interposer through via 114 may electrically connect the interposer upper interconnect structure INUW to the interposer lower interconnect structure INLW.

The interposer upper interconnect structure INUW may include an interposer upper interconnect layer 118, an interposer upper via 120, and an interposer upper insulating layer 122. The interposer upper interconnect layer 118 and the interposer upper via 120 may be electrically connected to each other. The interposer upper interconnect layer 118 and the interposer upper via 120 may include conductive material. For example, interposer upper interconnect layer 118 and the interposer upper via 120 may include a metal layer, for example, a copper layer. The interposer upper insulating layer 122 may be located on the interposer body INBD and may insulate between the interposer upper interconnect layer 118 and the interposer upper via 120.

The interposer lower interconnect structure INLW may include an interposer lower interconnect layer 126 and an interposer lower insulating layer 128. The interposer lower interconnect layer 126 may include a conductive material. For example, in at least some example embodiments, the interposer lower interconnect layer 126 may including a metal layer, for example, a copper layer. The interposer lower insulating layer 128 may be located below the interposer body INBD and may insulate among the interposer lower interconnect layers 126. The interposer lower pad 130 may be located below the interposer lower interconnect structure INLW and may be electrically connected to the external connection terminal 304.

The interposer through via 114 may pass through an upper portion and a lower portion of the interposer body INBD. The interposer through via 114 may include a conductive material. For example, in at least some example embodiments, the interposer through via 114 may include a metal, for example, copper. The interposer through via 114 may electrically connect the interposer upper via 120 to the interposer lower interconnect layer 126.

The bridge devices 104 and 104-1 may be arranged in the interposer body INBD. The bridge devices 104 and 104-1 may be mounted on the interposer lower interconnect structure INLW and may be molded by the interposer molding layer 116. According to some example embodiments, different from the example illustrated, the bridge devices 104 and 104-1 may not be included in the semiconductor package PK1. Additionally, the semiconductor package PK1 of FIG. 1 includes the two bridge devices 104 and 104-1; however, the examples are not limited thereto, and, in at least some example embodiments, the semiconductor package PK1 may include only one bridge device.

The bridge device 104 may include a bridge body 106, a bridge interconnect layer 108, and a bridge insulating layer 110. The bridge device 104 may include a bridge pad 112 electrically connected to the bridge interconnect layer 108. The bridge pad 112 may be electrically connected to the interposer upper via 120.

The electronic devices 132 and 136 may be located on the interposer structure INCS and may be electrically connected to the interposer upper interconnect structure INUW. The electronic devices 132 and 136 may include memory devices, central processing units (CPU), and/or graphics processing units (GPU). An interposer upper pad 123 may further be arranged on the interposer upper interconnect structure INUW. The electronic devices 132 and 136 may include electronic device bodies 133 and 135 and electronic device pads 134 and 138. For example, in at least some example embodiments, the electronic devices 132 and 136 may include a memory storing weights and/or other parameter for machine learning, and a GPU configured to perform a machine learning operation based on the parameters stored in the memory.

The electronic device pads 134 and 138 of the electronic devices 132 and 136 may be electrically connected to the interposer upper pad 123 through a first internal connection terminal 124. The first internal connection terminal 124 may include a solder ball. In the semiconductor package PK1 of FIG. 2, the plurality of electronic devices, that is, the two electronic devices 132 and 136, are illustrated. However, the semiconductor package PK1 may include only one electronic device and/or three or more electronic devices.

The electronic mold layer 140 may mold the electronic devices 132 and 136 on the interposer structure INCS. The electronic mold layer 140 may include a resin, for example, epoxy. The electronic mold layer 140 may be arranged at both side walls and lower portions of the electronic device bodies 133 and 135. The electronic mold layer 140 may be arranged between the electronic device pads 134 and 138, between the interposer upper pads 123, and between the first internal connection terminals 124.

The optical device package PHPK1 may be located to be in contact with the electronic mold layer 140 on the interposer structure INCS at a side of the electronic device 136. The optical device package PHPK1 may be electrically connected to the interposer upper interconnect structure INUW. An example of the optical device package PHPK1 is illustrated in detail in FIG. 3. FIG. 3 illustrates that in the optical device package PHPK1, a protective layer 96 may be arranged on a substrate optical waveguide 54 to protect the substrate optical waveguide 54. In at least some example embodiments, the protective layer 96 may be removed, and then, the optical connector structure OPST may be arranged on the substrate optical waveguide 54.

The optical device package PHPK1 may include a glass substrate 10, a cavity 62 (at least a portion of which is located below an upper surface of the glass substrate 10), the substrate optical waveguide 54 located on the upper surface of the glass substrate 10, and an inner electronic device 78 located in the cavity 62. The inner electronic device 78 may be mounted in the cavity 62.

A substrate pad 76 may be arranged on the glass substrate 10. A substrate through via 66 passing through an upper portion and a lower portion of the glass substrate 10 may be arranged in the glass substrate 10. The substrate optical waveguide 54 may be formed on the upper surface of the glass substrate 10. The substrate optical waveguide 54 may include an ion exchanged optical waveguide formed on the glass substrate 10. A method of manufacturing the substrate optical waveguide 54 will be described in detail below.

The optical device package PHPK1 may include, below the glass substrate 10, a substrate redistribution structure SRD electrically connected to the interposer upper interconnect structure INUW, and may include an optical device 84 located on the inner electronic device 78. The substrate redistribution structure SRD may include a substrate redistribution layer 68 and a substrate redistribution insulating layer 72.

The substrate pad 76 may be electrically connected to the substrate redistribution structure SRD through the substrate through via 66. A substrate redistribution pad 74 may be arranged below the substrate redistribution structure SRD. The substrate redistribution pad 74 may be electrically connected to the interposer upper pad 123.

The optical device 84 may be electrically connected to the inner electronic device 78 and the substrate redistribution structure SRD. The optical device 84 may include an optical device body 86, an optical device pad 88, and an optical device bonding pad 90. The inner electronic device 78 may include an inner electronic device body 80 and an inner electronic device bonding pad 82.

The optical device pad 88 may be electrically connected to the substrate pad 76 through a second internal connection terminal 94. The optical device bonding pad 90 may be bonded and electrically connected to the inner electronic device bonding pad 82. The optical device pad 88 may be electrically connected to the substrate redistribution structure SRD through the substrate pad 76 and the substrate through via 66.

The optical device 84 may include a device optical waveguide 92 coupled to the substrate optical waveguide 54. The substrate optical waveguide 54 may overlap the device optical waveguide 92. The substrate optical waveguide 54 may be optically connected to the device optical waveguide 92 by an evanescent coupling method.

The optical device package PHPK1 may include an optical mold layer 98 for molding the optical device 84, the glass substrate 10, and the inner electronic device 78. The optical mold layer 98 may be located on a side surface of the glass substrate 10. The optical mold layer 98 may be located on both side surfaces of the optical device body 86, below the optical device body 86, and on both side surfaces of the inner electronic device body 80.

The optical mold layer 98 may be located between the optical device pads 88, between the substrate pads 76, and in the cavity 62. A side surface of the optical mold layer 98 may be located to be in contact with a side surface of the electronic mold layer 140. The optical mold layer 98 may include a resin layer, for example, epoxy resins.

The optical connector structure OPST may include an optical fiber 152, an optical fiber protective layer 154, and an optical connector 156. The optical connector structure OPST may be connected to a side of the optical device package PHPK1. The optical fiber 152 of the optical connector structure OPST may be optically coupled to the substrate optical waveguide 54. The optical fiber 152 of the optical connector structure OPST may be horizontally coupled to the substrate optical waveguide 54.

As illustrated in FIG. 2, in the semiconductor package PK1, an optical signal OPA may be input through the optical fiber 152, and the input optical signal OPA may be input to the device optical waveguide 92 of the optical device 84 through the substrate optical waveguide 54. The input optical signal OPA may be converted into an electrical signal EPA by the optical device 84.

The electrical signal EPA may be input to the electronic device 136 through the optical device pad 88, the second internal connection terminal 94, the substrate pad 76, the substrate through via 66, the substrate redistribution layer SRD, and the interposer upper interconnect structure INUW. The electrical signal EPA may also be input to the inner electronic device 78 through the optical device bonding pad 90 and the inner electronic device bonding pad 82.

In the semiconductor package PK1 according to the at least one example embodiment described above, the optical device package PHPK1 may be arranged, to be in contact with the electronic device 136. In other words, in the semiconductor package PK1 according to at least one example embodiment, the electronic device 136 and the optical device package PHPK1 may be arranged to be adjacent to each other.

Accordingly, in the semiconductor package PK1 according to at least one example embodiment, the distance of the electrical signal EPA between the electronic device 136 and the optical device package PHPK1 may be reduced, and thus, bandwidth density and/or energy efficiency may be increased. In addition, in the semiconductor package PK1 according to at least one example embodiment, the substrate optical waveguide 54 and the device optical waveguide 92 may be optically coupled to each other by an evanescent coupling method, and thus, optical coupling loss may be reduced.

FIGS. 4 to 10 are cross-sectional views for describing a method of manufacturing the optical device package PHPK1 of FIGS. 1 to 3.

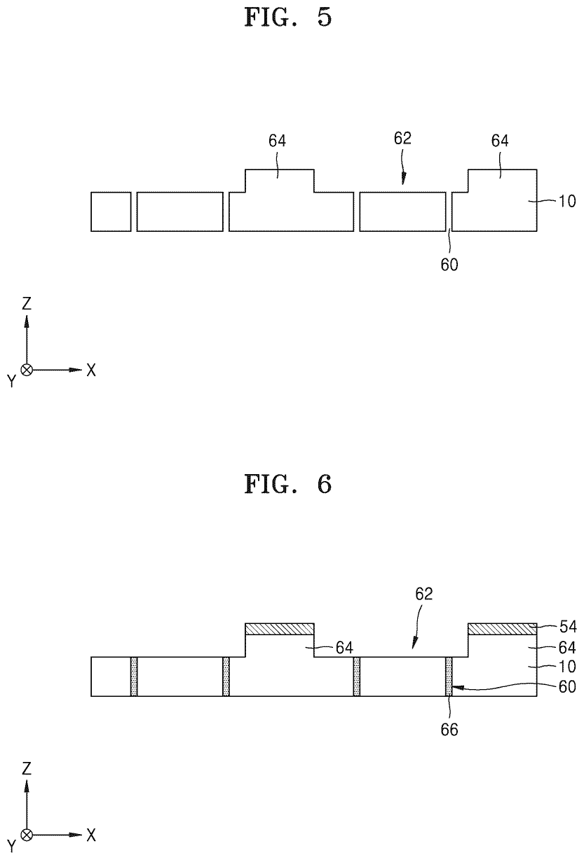

Referring to FIG. 4, the glass substrate 10 may be prepared. Referring to FIG. 5, a substrate through via hole 60, the cavity 62, and a protrusion portion 64 may be formed in the glass substrate 10 by using, e.g., a laser induced dry etching process. The laser induced dry etching process is a high-precision fine-processing process for selectively removing the glass substrate 10 by using a laser beam.

The laser induced dry etching process may include a process of irradiating a laser beam onto a surface of the glass substrate 10 to locally heat and activate the surface of the glass substrate 10, a process of applying a reactive gas (for example, CF₄, CHCIF₂, or C2H₂F₄) to cause a chemical reaction with the surface activated by the laser beam, and a process of selectively removing a glass material by forming a volatile product through a laser induced thermochemical reaction.

The substrate through via hole 60 may pass through an upper surface and a lower surface of the glass substrate 10. The cavity 62 may be located in the substrate through via hole 60 and below the upper surface of the glass substrate 10. The protrusion portion 64 may be formed by (or define) the cavity 62. The protrusion portion 64 may be located at both sides of the cavity 62. According to some example embodiments, after forming the cavity 62 and the protrusion portion 64, the substrate through via hole 60 may be formed. FIG. 5 illustrates only two cavities 62 for convenience; however, more or fewer cavities 62 may be produced.

Referring to FIG. 6, the substrate through via 66 may be formed in the substrate through via hole 60. For example, in at least some example embodiments, a metal layer, for example, a copper layer, may be buried in the substrate through via hole 60 to form the substrate through via 66. Next, the substrate optical waveguide 54 may be formed in the protrusion portion 64 of the glass substrate 10.

The substrate optical waveguide 54 may include an ion exchanged optical waveguide formed on the glass substrate 10. A method of forming the substrate optical waveguide 54 will be described in detail below.

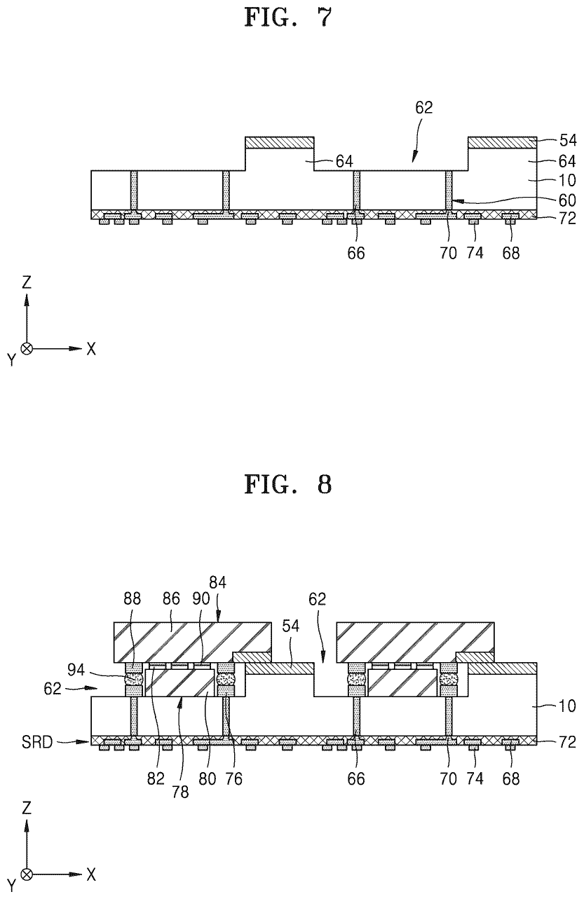

Referring to FIG. 7, the substrate redistribution structure SRD electrically connected to the substrate through via 66 may be formed below the glass substrate 10. The substrate redistribution structure SRD may include the substrate redistribution layer 68 and the substrate redistribution insulating layer 72. The substrate redistribution layer 68 may include a conductive material. For example, according to at least some example embodiments, the substrate redistribution layer 68 may include, a metal layer, for example, a copper layer. The substrate redistribution structure SRD may be configured to redistribute the substrate through via 66.

The substrate redistribution pad 74 may be formed below the substrate redistribution structure SRD, that is, below the substrate redistribution layer 68. The substrate redistribution pad 74 may include a conductive material. For example, according to at least some example embodiments, the substrate redistribution pad 74 may include a metal layer, for example, a copper layer. The substrate redistribution pad 74 may be electrically connected to the substrate redistribution layer 68.

Referring to FIG. 8, the inner electronic device 78 may be mounted in the cavity 62 of the glass substrate 10. According to some example embodiments, the inner electronic device 78 may be bonded in the cavity 62 of the glass substrate 10 by using an adhesive. The inner electronic device 78 may include the inner electronic device body 80 and the inner electronic device bonding pad 82. The inner electronic device bonding pad 82 may be arranged on an upper surface of the inner electronic device 78.

The substrate pad 76 may be formed in the substrate through via 66 in the cavity 62 of the glass substrate 10. The substrate pad 76 may be electrically connected to the substrate redistribution structure SRD through the substrate through via 66.

The optical device 84 may be mounted on the substrate pad 76, the inner electronic device 78, and the substrate optical waveguide 54. The optical device 84 may include the optical device body 86, the optical device pad 88, and the optical device bonding pad 90. The optical device pad 88 may be formed on a lower surface of the optical device body 86. The optical device pad 88 may be located on the substrate pad 76 and may be electrically connected to the substrate pad 76 through the second internal connection terminal 94.

The optical device bonding pad 90 may be located on the inner electronic device bonding pad 82. The optical device bonding pad 90 may be bonded and electrically connected to the inner electronic device bonding pad 82. The optical device bonding pad 90 may be electrically connected to the substrate redistribution structure SRD through the substrate pad 76 and the substrate through via 66.

The optical device 84 may include the device optical waveguide 92 coupled to the substrate optical waveguide 54. The device optical waveguide 92 may be arranged to overlap the substrate optical waveguide 54. The device optical waveguide 92 may be arranged to overlap a partial surface of the substrate optical waveguide 54. The partial surface of the substrate optical waveguide 54 may not overlap the optical device 84, that is, the device optical waveguide 92, and thus, may be exposed.

Thus, the device optical waveguide 92 may be optically connected to the substrate optical waveguide 54 by an evanescent coupling method. According to some example embodiments, the device optical waveguide 92 may be optically connected to the substrate optical waveguide 54 through an edge coupling method or a grating coupling method, according to the structure and the size of the optical device 84 and a formation location of the substrate optical waveguide 54.

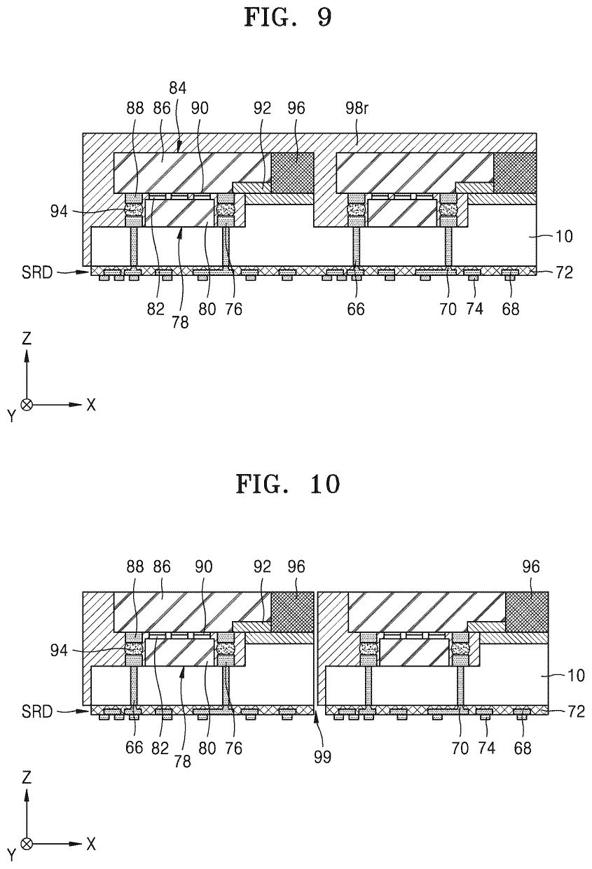

Referring to FIG. 9, the protective layer 96 may be formed on the substrate optical waveguide 54 exposed by not overlapping the device optical waveguide 92. The protective layer 96 may include a resin layer, for example, a material, such as polyimide. The protective layer 96 may be formed to protect the substrate optical waveguide 54 in a subsequent molding process.

An optical mold material layer 98r for molding the inner electronic device 78, which is mounted on the glass substrate 10, and the optical device 84 may be formed. The optical mold material layer 98r may be formed on a side surface of the glass substrate 10. The optical mold material layer 98r may be formed on an upper surface and both side surfaces of the optical device body 86, below the optical device body 86, and on both side surfaces of the inner electronic device body 80.

The optical mold material layer 98r may be formed between the optical device pads 88, between the substrate pads 76, and in the cavity 62. The optical mold material layer 98r may include a resin layer, for example, epoxy resins.

Referring to FIG. 10, the optical mold layer 98 may be formed by etch-backing the optical mold material layer 98r with an upper surface of the optical mold material layer 98r as an etch stopping point. The optical mold layer 98 may be formed on a side surface of the glass substrate 10. The optical mold layer 98 may be formed on both side surfaces of the optical device body 86, below the optical device body 86, and on both side surfaces of the inner electronic device body 80.

The optical mold layer 98 may be formed between the optical device pads 88, between the substrate pads 76, and in the cavity 62. Next, the glass substrate 10 may be cut along a cutting line 99 for each of the optical device 84 and the inner electronic device 78, to form the optical device package PHPK1.

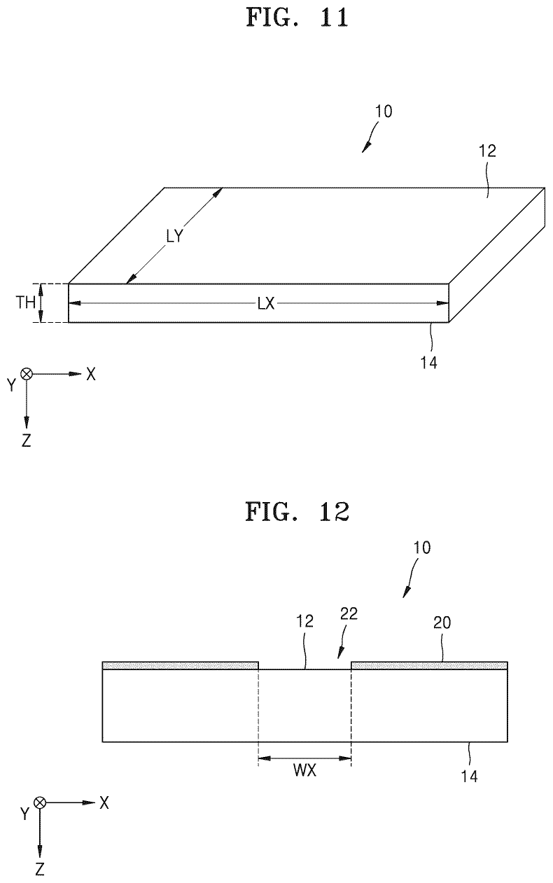

FIGS. 11 to 18 are views for describing a method of manufacturing the substrate optical waveguide 54 of the optical device package PHPK1 of FIGS. 1 to 3.

FIG. 11 is a perspective view of the glass substrate 10. The glass substrate 10 may have a shape of a sheet having an upper end surface 12 and a lower end surface 14. The glass substrate 10 may have bulk refractive index represented as n₀. The glass substrate 10 may have a length LX in an X direction, which is, for example, 0.1 meters (m) or greater. The glass substrate 10 may have a length LY in a Y direction, which is, for example, 0.1 m or greater. The glass substrate 10 may have a thickness TH in a Z direction, which is, for example, about 0.3 mm to about 5 mm. The glass substrate 10 may include alkali-aluminosilicate glass.

According to some example embodiments, the glass substrate 10 may include SiO₂ of about 70 mol % to about 85 mol %, Al₂O₃ of about 0 mol % to about 5 mol %, B₂O₃ of about 0 mol % to about 5 mol %, Na₂O of about 3 mol % to about 10 mol %, K₂O of about 0 mol % to about 12 mol %, ZnO of about 0 mol % to about 4 mol %, MgO of about 3 mol % to about 12 mol %, CaO of about 0 mol % to about 5 mol %, SrO of about 0 mol % to about 3 mol %, BaO of about 0 mol % to about 3 mol %, and SnO₂ of about 0.01 mol % to about 0.5 mol %.

According to some example embodiments, the glass substrate 10 may include SiO₂ of about 65. 79 mol % to about 78.17 mol %, Al₂O₃ of about 2.94 mol % to about 12.12 mol %, B₂O₃ of about 0 mol % to about 11.16 mol %, Li₂O of about 0 mol % to about 2.06 mol %, Na₂O of about 3.52 mol % to about 13.25 mol %, K₂O of about 0 mol % to about 4.83 mol %, ZnO of about 0 mol % to about 3.01 mol %, MgO of about 0 mol % to about 8.72 mol %, CaO of about 0 mol % to about 4.24 mol %, SrO of about 0 mol % to about 6.17 mol %, BaO of about 0 mol % to about 4.3 mol %, and SnO₂ of about 0.07 mol % to about 0.11 mol %.

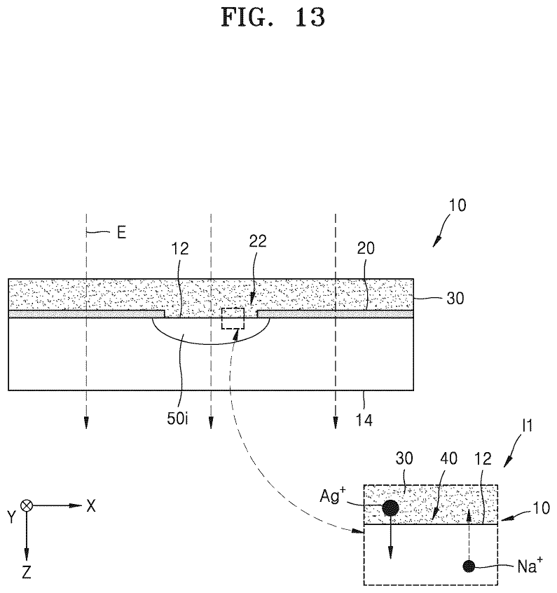

FIG. 12 is a cross-sectional view for describing an operation of forming a mask 20 on the glass substrate 10. As illustrated in FIG. 12, the mask 20 may be located on the upper end surface 12 of the glass substrate 10. The mask 20 may include an open hole 22 in the upper end surface 12.

The mask 20 may include a material layer for protecting against the diffusion of atoms or ions into the glass substrate 10. The mask 20 may include, for example, at least one of aluminum, titanium, and/or silicon dioxide. The composition of the mask 20 may be different from the glass substrate 100. According to some example embodiments, the hole 22 may be formed to extend to be narrow in the X direction and long in the Y direction.

According to some example embodiments, the hole 22 may be formed to have a width WX of about 1 μm to about 10 μm to form the substrate optical waveguide in a single mode. The hole 22 may have a width WX of about 10 micrometers μm to about 50 μm in order to form the substrate optical waveguide in a multi-mode.

FIG. 13 is a cross-sectional view for describing a silver salt bath 30 applied to the glass substrate 10 and an initial ion exchanged area 50i formed in the glass substrate 10. FIG. 13 also includes an enlarged cross-sectional view I1 of the hole 22. The silver salt bath 30 may include AgNO₃.

The glass substrate 10 on which the mask 20 is formed may be positioned in the silver salt bath 30. A first step diffusion process may be performed on the glass substrate 10 located in the silver salt bath 30 to form the initial ion exchanged area 50i in the glass substrate 10.

When the first step diffusion process is performed, Ag+ ions of the silver salt bath 30 may be exchanged with Na+ ions of the glass substrate 10 as illustrated in the enlarged cross-sectional view I1, so as to form the initial ion exchanged area 50i in the glass substrate 10. The initial ion exchanged area 50i may include an initial Ag—Na ion exchanged area. An ion exchanged interface 40 may be formed on the upper end surface 12 of the glass substrate 10.

A process condition of the first step diffusion process may include a diffusion temperature TD in the range of about 250° C. to about 400° C., a silver concentration C_{Ag} in the range of about 1 wt % to about 25 wt %, and a diffusion time tD in the range of about 10 minutes to about 200 hours. According to some example embodiments, during the first step diffusion process, an electric field E may be applied.

FIG. 14 is a cross-sectional view showing that the mask 20 formed on the glass substrate 10 is removed. FIG. 14 includes a graph showing a refractive index change in the initial ion exchanged area 50i.

The initial ion exchanged area 50i may have a maximum refractive index n₁ on the upper end surface 12 of the glass substrate 10. The maximum refractive index n₁ may decrease until the maximum refractive index n₁ reaches the bulk refractive index n₀ in the glass substrate 10. The initial ion exchanged area 50i may have an initial refractive index profile n(z) monotonously decreasing to the depth of the glass substrate 10. The maximum change of the refractive index of the initial ion exchanged area 50i may be n₁-n₀.

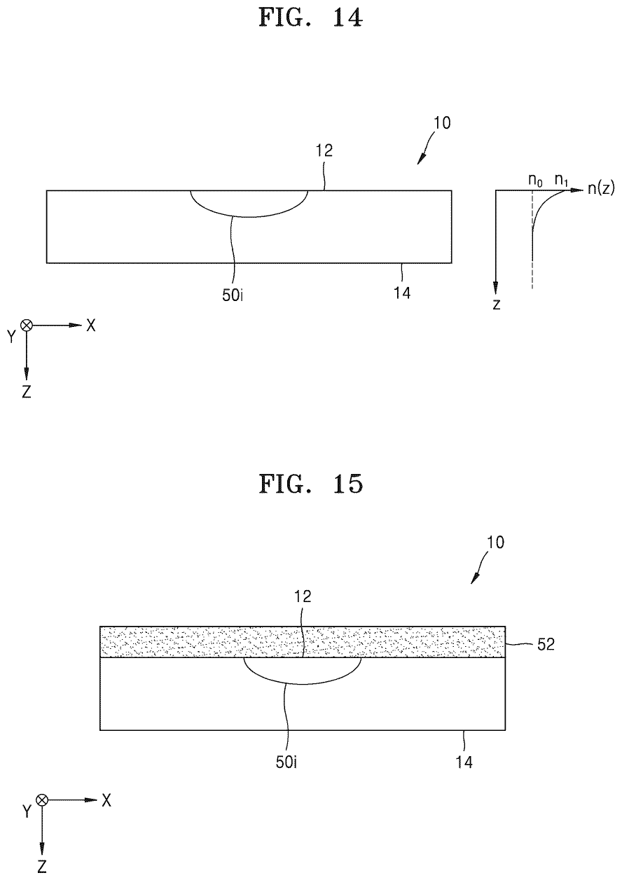

FIG. 15 is a cross-sectional view showing that a sodium salt bath 52 is applied onto the initial ion exchanged area 50i. The glass substrate 10 on which the initial ion exchanged area 50i is formed may be positioned in the sodium salt bath 52. The sodium salt bath 52 may include NaNO₃.

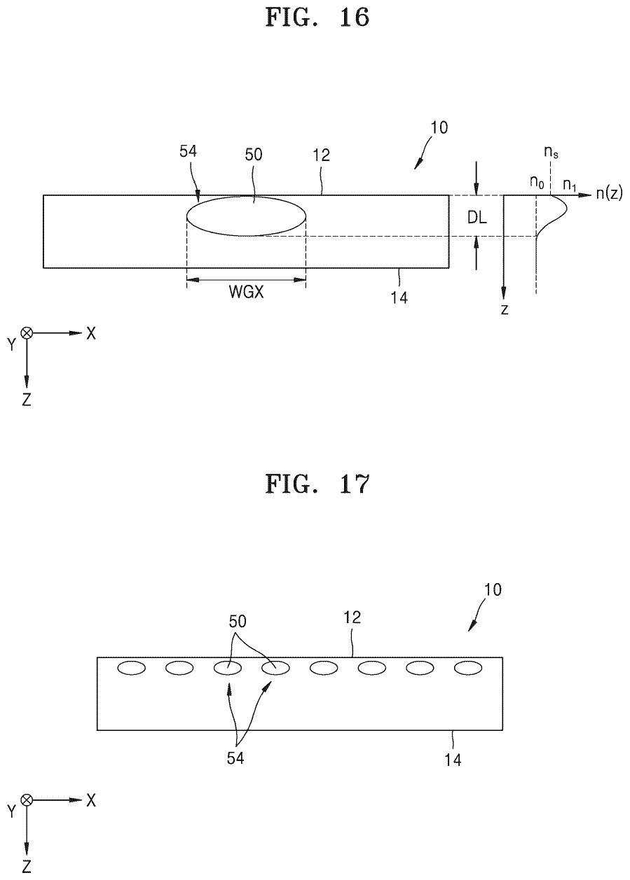

FIG. 16 is a cross-sectional view for describing a final ion exchanged area 50 formed in the glass substrate 10. A second step diffusion process may be performed on the glass substrate 10 arranged in the sodium salt bath 52 (see FIG. 15) to form the final ion exchanged area 50 buried in the glass substrate 10.

When second thermal processing, that is, the second step diffusion process, is performed, Ag+ ions of the glass substrate 10 may move to the upper end surface 12 in order to be exchanged with Na+ ions of the sodium salt bath 52 (see FIG. 15). Thus, the initial ion exchanged area 50i may be changed to the final ion exchanged area 50. The final ion exchanged area 50 may be formed in the glass substrate 10. The final ion exchanged area 50 may include a final Ag—Na ion exchanged area.

A process condition of the second step diffusion process may include a diffusion temperature TD in the range of about 250° C. to about 400° C. and a diffusion time tD in the range of about 5 minutes to about 46 minutes. According to some example embodiments, during the second step diffusion process, an electric field E may be applied.

As illustrated in FIG. 16, initial ion exchanged area 50i is changed the final ion exchanged area 50 according to the second step diffusion process. The final ion exchanged area 50 has a refractive index profile having a maximum value of n₁ and formed below the upper end surface 12. According to some example embodiments, the final ion exchanged area 50 may extend to be narrow in the X direction and long in the Y direction. The final ion exchanged area 50 may correspond to the substrate optical waveguide 54.

The final ion exchanged area 50 may have a graded refractive index profile n(x, z), whereby the final ion exchanged area 50 may have a maximum refractive index n₁ below the upper end surface 12 and a minimum refractive index n₀ at a depth DL. The upper end surface 12 of the final ion exchanged area 50 may have a refractive index of ns, which may be less than the maximum refractive index n₁. The upper end surface 12 of the final ion exchanged area 50 may approach the bulk refractive index n₀ rather than the maximum refractive index n₁. The final ion exchanged area 50 may have a width of WGX in the X direction.

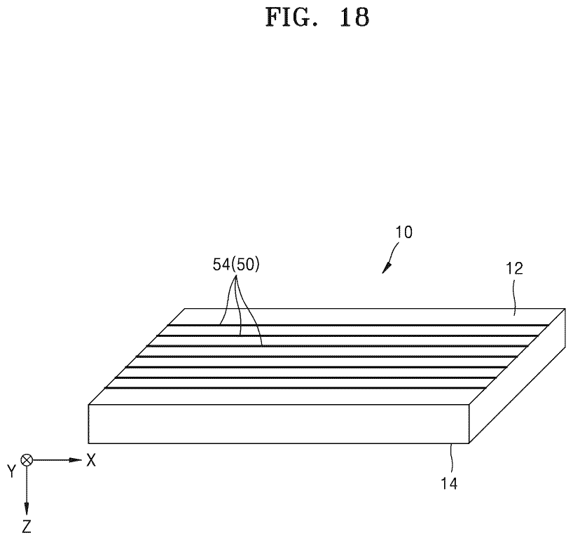

Referring to FIGS. 17 and 18, FIGS. 17 and 18 are a cross-sectional view and a perspective view, respectively, for describing the plurality of final ion exchanged areas 50 formed on the glass substrate 10. The final ion exchanged areas 50 may correspond to the substrate optical waveguide 54. The final ion exchanged areas 50 may be located to be apart from each other in the X direction. The final ion exchanged areas 50 may be located to extend in the Y direction.

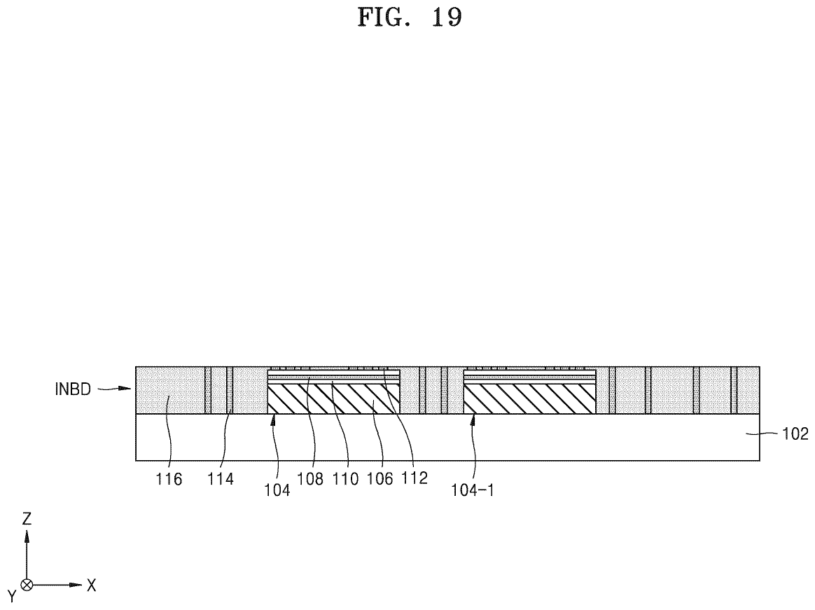

FIGS. 19 to 22 are cross-sectional views for describing a method of manufacturing the optical device package PHPK1 of FIGS. 1 to 3.

Referring to FIG. 19, FIG. 19 shows an operation of forming the bridge devices 104 and 104-1, the interposer body INBD, and the interposer through via 114 on a carrier substrate 102. After arranging the bridge devices 104 and 104-1 on the carrier substrate 102, the interposer body INBD for molding the bridge devices 104 and 104-1 may be formed.

The manufacturing process in which the bridge devices 104 and 104-1, the interposer body INBD, and the interposer through via 114 are formed on the carrier substrate 102, may be performed by using a chip on wafer (COW) process.

Each of the bridge devices 104 and 104-1 may include the bridge body 106, the bridge interconnect layer 108, and the bridge insulating layer 110. Each of the bridge devices 104 and 104-1 may include the bridge pad 112 electrically connected to the bridge interconnect layer 108. The interposer body INBD may include the interposer molding layer 116 for molding the bridge devices 104 and 104-1. The interposer molding layer 116 may include a resin layer, for example, epoxy.

The interposer through via 114 may be formed in the interposer body INBD. The interposer through via 114 may pass through an upper portion and a lower portion of the interposer body INBD. The interposer through via 114 may include a conductive material. For example, according to at least some example embodiments, the interposer through via 114 may include a metal, for example, a copper.

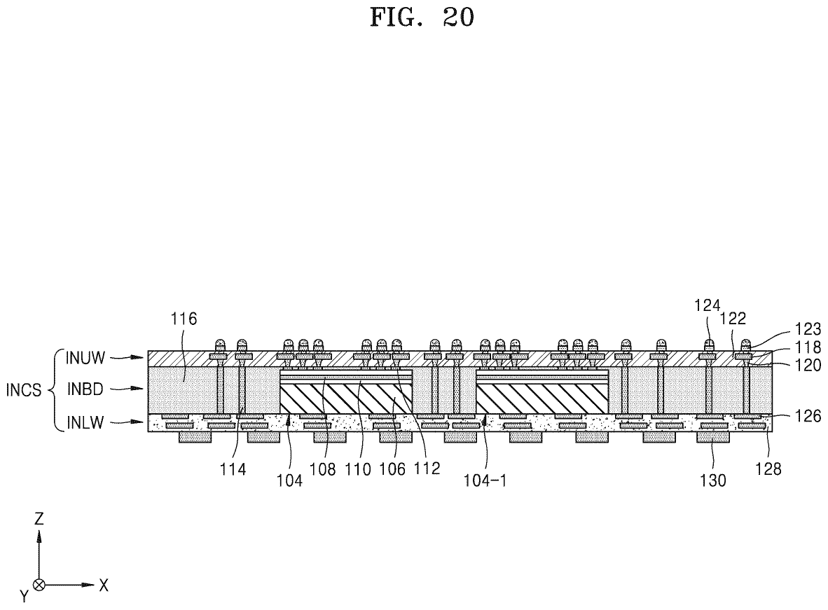

Referring to FIG. 20, FIG. 20 shows an operation of forming the interposer upper interconnect structure INUW, the interposer upper pad 123, the first internal connection terminal 124, the interposer lower interconnect structure INLW, and the interposer lower pad 130. The interposer upper interconnect structure INUW may be formed above the interposer body INBD.

The interposer upper interconnect structure INUW may include the interposer upper interconnect layer 118, the interposer upper via 120, and the interposer upper insulating layer 122. The interposer upper interconnect layer 118 and the interposer upper via 120 may be electrically connected to each other.

The interposer upper interconnect layer 118 and the interposer upper via 120 may include a conductive material. For example, according to at least some example embodiments, the interposer upper interconnect layer 118 may include a metal, for example, a copper. The interposer upper pad 123 and the first internal connection terminal 124 may be formed on the interposer upper interconnect structure INUW.

The interposer lower interconnect structure INLW may be formed below the interposer body INBD. The interposer lower interconnect structure INLW may include the interposer lower interconnect layer 126 and the interposer lower insulating layer 128. The interposer lower interconnect layer 126 may include a conductive material. For example, according to at least some example embodiments, the interposer lower interconnect layer 127 may include a metal layer, for example, a copper layer.

The interposer through via 114 may electrically connect the interposer upper interconnect structure INUW to the interposer lower interconnect structure INLW. The interposer body INBD, the interposer upper interconnect structure INUW, the interposer lower interconnect structure INLW, and the interposer through via 114 may form the interposer structure INCS. The interposer lower pad 130 may further be formed below the interposer lower interconnect structure INLW.

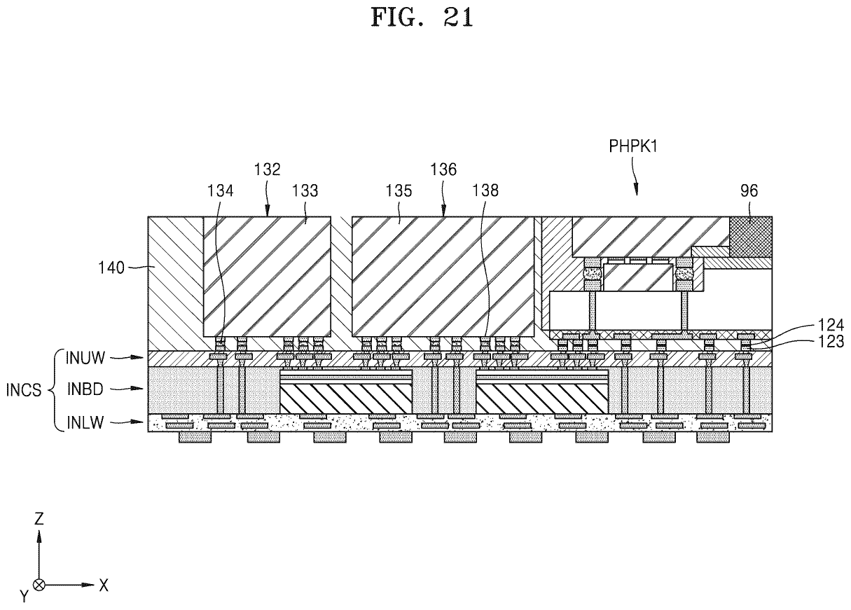

Referring to FIG. 21, an operation of forming the electronic mold layer 140 after mounting the electronic devices 132 and 136 and the optical device package PHPK1 is shown. The electronic devices 132 and 136 may be mounted on the interposer upper pad 123 on the interposer structure INCS and the first internal connection terminal 124. The electronic devices 132 and 136 may include the electronic device bodies 133 and 135 and the electronic device pads 134 and 138. The electronic device pads 134 and 138 may be electrically connected to the interposer upper pad 123 through the first internal connection terminal 124.

The optical device package PHPK1 may be mounted on the interposer upper pad 123 on the interposer structure INCS and the first internal connection terminal 124. The optical device package PHPK1 may include, on the substrate optical waveguide 54, the protective layer 96 for protecting the substrate optical waveguide 54. The optical device package PHPK1 is described above with reference to FIGS. 1 to 3, and thus, a repeat description thereof is omitted here.

After forming an electronic mold material layer for molding, on the interposer structure INCS, the electronic devices 132 and 136 and the optical device package PHPK1, the electronic mold material layer may be planarization-etched to form the electronic mold layer 140 for molding the electronic devices 132 and 136. The electronic mold layer 140 may include a resin layer, for example, epoxy.

The electronic mold layer 140 may be formed at both side walls and lower portions of the electronic device bodies 133 and 135. The electronic mold layer 140 may be arranged between the electronic device pads 134 and 138, between the interposer upper pads 123, and between the first internal connection terminals 124. A side surface of the electronic mold layer 140 may be located to be in contact with a side surface of the optical mold layer 98.

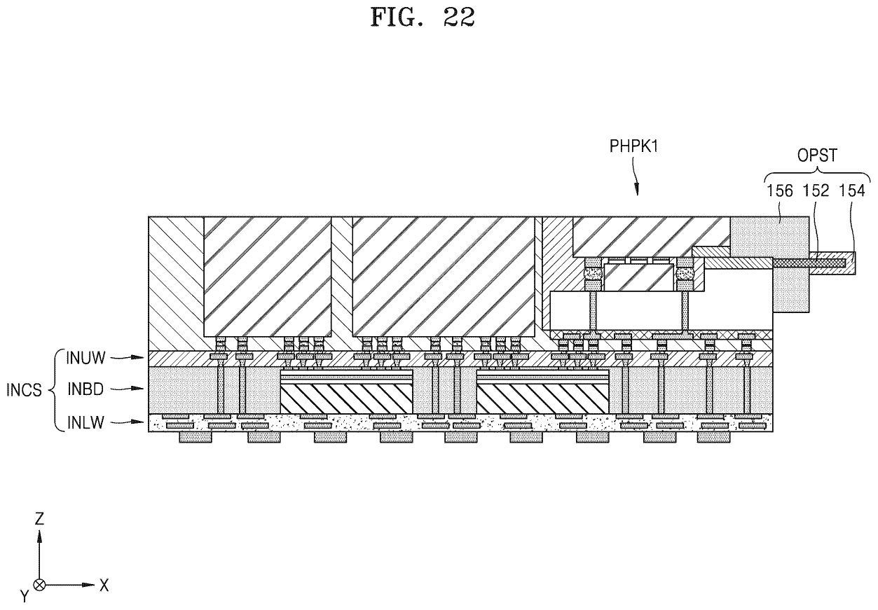

Referring to FIG. 22, FIG. 22 shows an operation of connecting the optical connector structure OPST. After removing the protective layer 96 formed on the substrate optical waveguide 54 of the optical device package PHPK1, the optical connector structure OPST may be connected. The optical connector structure OPST may include the optical fiber 152, the optical fiber protective layer 154, and the optical connector 156.

The optical connector structure OPST may be connected to a side of the optical device package PHPK1. The optical fiber 152 of the optical connector structure OPST may be optically coupled to the substrate optical waveguide 54. The optical fiber 152 of the optical connector structure OPST may be horizontally coupled to the substrate optical waveguide 54.

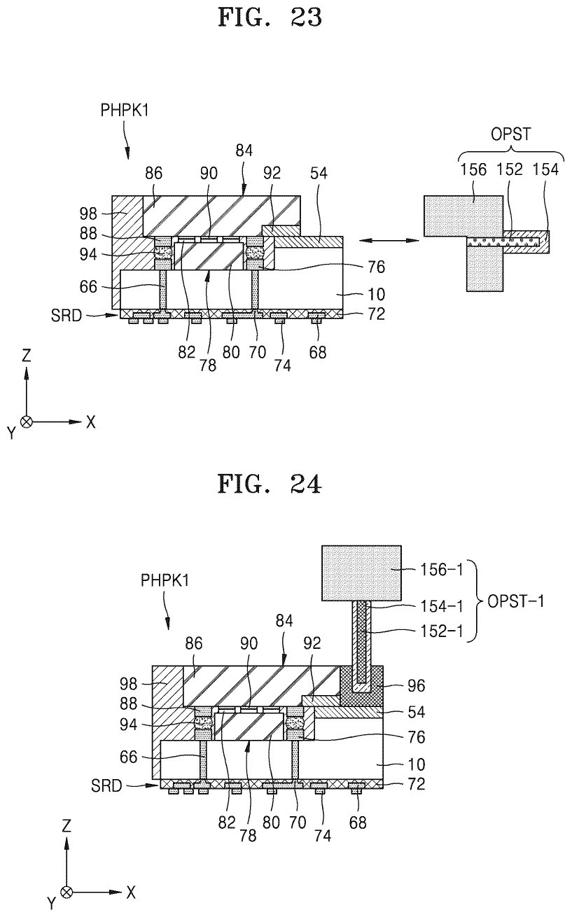

FIG. 23 is a view for describing an optical coupling relationship between the optical device package PHPK1 and the optical connector structure OPST according to at least one example embodiment.

In detail, FIG. 23 is provided to describe the optical connector structure OPST horizontally coupled to the substrate optical waveguide 54 of the optical device package PHPK1 illustrated in FIG. 22. The optical connector structure OPST may be connected at a side of the substrate optical waveguide 54 in an arrow direction, after removing the protective layer 96 (see FIG. 21) of the optical device package PHPK1.

The optical connector structure OPST may include the optical fiber 152, the optical fiber protective layer 154, and the optical connector 156, as described above. The optical fiber 152 of the optical connector structure OPST may be optically coupled to the substrate optical waveguide 54.

FIG. 24 is a view for describing an optical coupling relationship between the optical device package PHPK1 and an optical connector structure OPST-1 according to at least one example embodiment.

In detail, FIG. 24 may be the same as (or substantially similar to) FIG. 23, except for the optical connector structure OPST-1 being vertically coupled to the substrate optical waveguide 54 of the optical device package PHPK1. The optical connector structure OPST-1 may optically couple the substrate optical waveguide 54 and an optical fiber 152-1 to each other in a vertical direction, without removing the protective layer 96 (see FIG. 21) of the optical device package PHPK1.

In the optical device package PHPK1, the protective layer 96 may be formed on the substrate optical waveguide 54 exposed by not overlapping the device optical waveguide 92. According to some example embodiments, the protective layer 96 may include a resin layer transmitting infrared rays, for example, a material such as polyimide.

The optical connector structure OPST may include the optical fiber 152-1, an optical fiber protective layer 154-1, and an optical connector 156-1. The optical connector structure OPST-1, that is, the optical fiber 152-1, may be vertically coupled to the substrate optical waveguide 54 of the optical device package PHPK1. The optical fiber 152-1 may be coupled to the substrate optical waveguide 54 by being vertically apart therefrom.

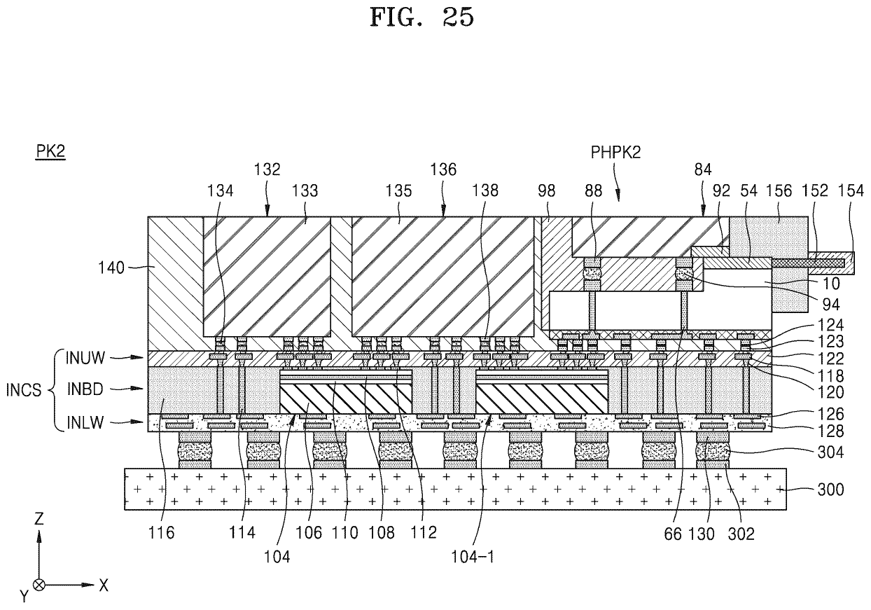

FIG. 25 is a cross-sectional view of a semiconductor package PK2 according to at least one example embodiment.

In detail, the semiconductor package PK2 may be the same as (or substantially similar to) the semiconductor package PK1 of FIGS. 1 to 3, except that the semiconductor package PK2 may not include the inner electronic device 78 (see FIGS. 1 to 3). In FIG. 25, the same reference numerals as in FIGS. 1 to 3 refer to the same members. In FIG. 25, the aspects described with reference to FIGS. 1 to 3 are briefly described or are not described.

The semiconductor package PK2 may include the main substrate 300, the interposer structure INCS, the bridge devices 104 and 104-1, the electronic devices 132 and 136, the electronic mold layer 140, the optical device package PHPK, and the optical connector structure OPST. Aspects about the main substrate 300, the interposer structure INCS, the bridge devices 104 and 104-1, the electronic devices 132 and 136, the electronic mold layer 140, and the optical connector structure OPST are described above, and thus, their descriptions are omitted.

The semiconductor package PK2 may include the optical device package PHPK2. The optical device package PHPK2 may include the glass substrate 10, the cavity 62, and the substrate optical waveguide 54. The substrate pad 76 may be arranged on the glass substrate 10, and the substrate through via 66 may be arranged in the glass substrate 10. The substrate optical waveguide 54 may be formed on an upper surface of the glass substrate 10. The substrate optical waveguide 54 may correspond to an ion exchanged optical waveguide formed on the glass substrate 10.

The optical device package PHPK2 may include, below the glass substrate 10, the substrate redistribution structure SRD electrically connected to the interposer upper interconnect structure INUW, and may include the optical device 84 on the glass substrate 10. The substrate redistribution structure SRD may include the substrate redistribution layer 68 and the substrate redistribution insulating layer 72.

The substrate pad 76 may be electrically connected to the substrate redistribution structure SRD through the substrate through via 66. The substrate redistribution pad 74 may be arranged below the substrate redistribution structure SRD. The substrate redistribution pad 74 may be electrically connected to the interposer upper pad 123.

The optical device 84 may be electrically connected to the inner electronic device 78 and the substrate redistribution structure SRD. The optical device 84 may include the optical device body 86, the optical device pad 88, and the optical device bonding pad 90. The optical device pad 88 may be electrically connected to the substrate pad 76 through the second internal connection terminal 94. The optical device bonding pad 90 may be electrically connected to the substrate redistribution structure SRD through the substrate pad 76 and the substrate through via 66.

The optical device 84 may include the device optical waveguide 92 coupled to the substrate optical waveguide 54. The substrate optical waveguide 54 may overlap the device optical waveguide 92. The substrate optical waveguide 54 may be optically connected to the device optical waveguide 92 by an evanescent coupling method.

The optical device package PHPK2 may include the optical device 84 and the optical mold layer 98 for molding the glass substrate 10. The optical mold layer 98 may be located on a side surface of the glass substrate 10. The optical mold layer 98 may be located on both side surfaces of the optical device body 86 and below the optical device body 86. The optical mold layer 98 may be located between the optical device pads 88, between the substrate pads 76, and in the cavity 62. A side surface of the optical mold layer 98 may be located to be in contact with a side surface of the electronic mold layer 140. The optical mold layer 98 may include a resin layer, for example, epoxy resins.

The optical connector structure OPST may include the optical fiber 152, the optical fiber protective layer 154, and the optical connector 156. The optical connector structure OPST may be connected to a side of the optical device package PHPK2. The optical fiber 152 of the optical connector structure OPST may be optically coupled to the substrate optical waveguide 54. The optical fiber 152 of the optical connector structure OPST may be horizontally coupled to the substrate optical waveguide 54.

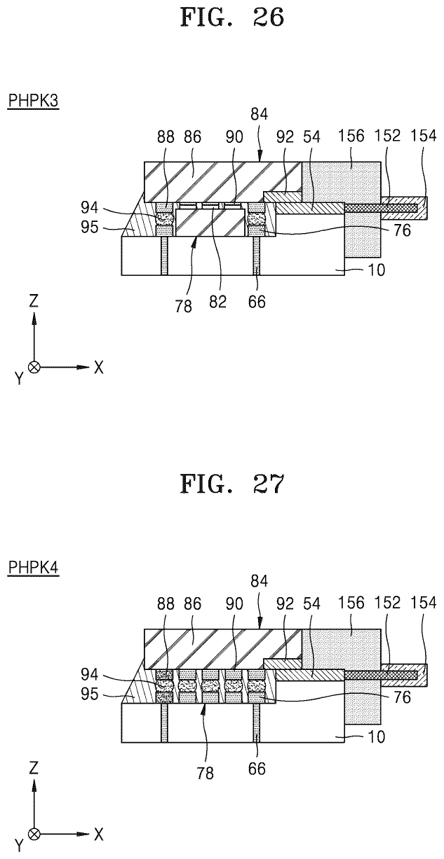

FIG. 26 is a cross-sectional view for describing an optical device package PHPK3 which may be included in a semiconductor package according to at least one example embodiment.

In detail, the optical device package PHPK3 may be the same as (or substantially similar to) the optical device package PHPK1 illustrated in FIGS. 1 to 3, except that the optical device package PHPK3 may further include an underfill layer 95. For convenience, the substrate redistribution structure SRD located below the glass substrate 10 is not illustrated in the optical device package PHPK3. In FIG. 26, the same reference numerals as in FIGS. 1 to 3 refer to the same members. In FIG. 26, the aspects described with reference to FIGS. 1 to 3 are briefly described or are not described.

The optical device package PHPK3 may include the glass substrate 10, the cavity 62 located below an upper surface of the glass substrate 10, the substrate optical waveguide 54 located on the upper surface of the glass substrate 10, and the inner electronic device 78 located in the cavity 62.

The substrate pad 76 may be arranged on the glass substrate 10. The substrate through via 66 passing through an upper portion and a lower portion of the glass substrate 10 may be arranged in the glass substrate 10.

The optical device package PHPK3 may include the optical device 84 located on the inner electronic device 78. The optical device 84 may include the optical device body 86, the optical device pad 88, and the optical device bonding pad 90. The inner electronic device 78 may include the inner electronic device body 80 and the inner electronic device bonding pad 82.

The optical device pad 88 may be electrically connected to the substrate pad 76 through the second internal connection terminal 94. The optical device bonding pad 90 may be bonded and electrically connected to the inner electronic device bonding pad 82. The optical device pad 88 may be electrically connected to the substrate pad 76 and the substrate through via 66.

The optical device 84 may include the device optical waveguide 92 coupled to the substrate optical waveguide 54. The substrate optical waveguide 54 may overlap the device optical waveguide 92. The substrate optical waveguide 54 may be optically connected to the device optical waveguide 92 by an evanescent coupling method.

The optical device package PHPK3 may include the underfill layer 95 covering the inner electronic device 78 and filling a lower portion of the optical device 84 and an upper portion of the glass substrate 10. The underfill layer 95 may be located below the optical device body 86 and on both side surfaces of the inner electronic device body 80. The underfill layer 95 may be located between the optical device pads 88, between the substrate pads 76, and in the cavity 62. The underfill layer 95 may include resins.

The optical connector structure OPST may include the optical fiber 152, the optical fiber protective layer 154, and the optical connector 156. The optical connector structure OPST may be connected to a side of the optical device package PHPK3. The optical fiber 152 of the optical connector structure OPST may be optically coupled to the substrate optical waveguide 54. The optical fiber 152 of the optical connector structure OPST may be horizontally coupled to the substrate optical waveguide 54.

FIG. 27 is a cross-sectional view for describing an optical device package PHPK4 which may be included in a semiconductor package according to at least one example embodiment.

In detail, the optical device package PHPK4 may be the same as (or substantially similar to) the optical device package PHPK1 illustrated in FIGS. 1 to 3, except that the optical device package PHPK4 may not include the inner electronic device 78 and may further include the underfill layer 95. For convenience, the substrate redistribution structure SRD located below the glass substrate 10 is not illustrated in the optical device package PHPK4. In FIG. 27, the same reference numerals as in FIGS. 1 to 3 refer to the same members. In FIG. 27, the aspects described with reference to FIGS. 1 to 3 are briefly described or are not described.

The optical device package PHPK4 may include the glass substrate 10, the cavity 62 located below an upper surface of the glass substrate 10, and the substrate optical waveguide 54 located on the upper surface of the glass substrate 10. The substrate pad 76 may be arranged on the glass substrate 10. The substrate through via 66 passing through an upper portion and a lower portion of the glass substrate 10 may be arranged in the glass substrate 10.

The optical device package PHPK4 may include the optical device 84 located in the cavity 62. The optical device 84 may include the optical device body 86, the optical device pad 88, and the optical device bonding pad 90. The optical device pad 88 may be electrically connected to the substrate pad 76 through the second internal connection terminal 94. The optical device pad 88 may be electrically connected to the substrate pad 76 and the substrate through via 66.

The optical device 84 may include the device optical waveguide 92 coupled to the substrate optical waveguide 54. The substrate optical waveguide 54 may overlap the device optical waveguide 92. The substrate optical waveguide 54 may be optically connected to the device optical waveguide 92 by an evanescent coupling method.

The optical device package PHPK4 may include the underfill layer 95 filling a lower portion of the optical device 84 and an upper portion of the glass substrate 10. The underfill layer 95 may be located below the optical device body 86. The underfill layer 95 may be located between the optical device pads 88, between the substrate pads 76, and in the cavity 62.

The optical connector structure OPST may include the optical fiber 152, the optical fiber protective layer 154, and the optical connector 156. The optical connector structure OPST may be connected to a side of the optical device package PHPK4. The optical fiber 152 of the optical connector structure OPST may be optically coupled to the substrate optical waveguide 54. The optical fiber 152 of the optical connector structure OPST may be horizontally coupled to the substrate optical waveguide 54.

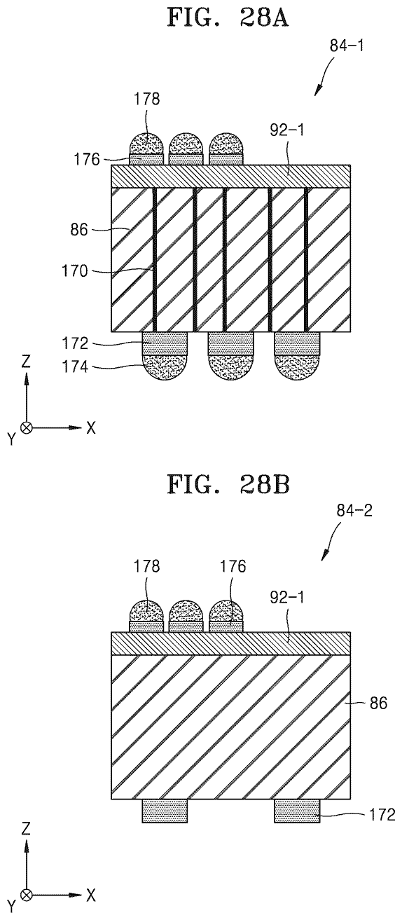

FIGS. 28A and 28B are, respectively, cross-sectional views for describing optical devices 84-1 and 84-2 which may be included in an optical device package according to at least one example embodiment.

In detail, various optical devices (for example, the optical devices 84-1 and 84-2) may be used for the optical device package according to at least one example embodiment. As illustrated in FIG. 28A, the optical device 84-1 may include the optical device body 86, an optical device through via 170, first and second optical device pads 172 and 176, first and second optical device connection terminals 174 and 178, and a device optical waveguide 92-1.

The first and second optical device pads 172 and 176 may be arranged below and above the optical device body 86, respectively. The first and second optical device connection terminals 174 and 178 may be arranged below and above the optical device body 86, respectively. The optical device through via 170 may pass through a lower surface and an upper surface of the optical device body 86.

The device optical waveguide 92-1 may be arranged on an upper surface of the optical device body 86. When the device optical waveguide 92-1 is arranged on the upper surface of the optical device body 86, the optical device 84 may be optically connected to the substrate optical waveguide (for example, 54 of FIGS. 1 to 3) based on an edge coupling method, without overlapping the substrate optical waveguide.

As illustrated in FIG. 28B, the optical device 84-2 may include the optical device body 86, the first and second optical device pads 172 and 176, the second optical device connection terminal 178, and the device optical waveguide 92-1. The first and second optical device pads 172 and 176 may be arranged below and above the optical device body 86, respectively. The second optical device connection terminal 178 may be arranged above the optical device body 86.

The device optical waveguide 92-1 may be arranged on an upper surface of the optical device body 86. When the device optical waveguide 92-1 is arranged on the upper surface of the optical device body 86, the optical device 84 may be optically connected to the substrate optical waveguide (for example, 54 of FIGS. 1 to 3) by an edge coupling method, without overlapping the substrate optical waveguide.

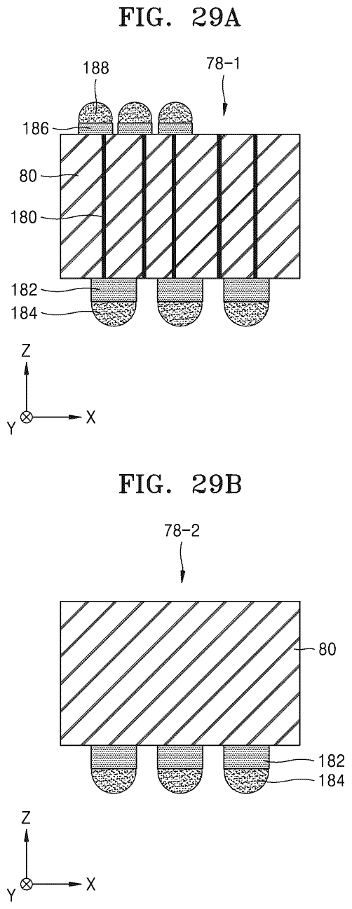

FIGS. 29A and 29B are, respectively, cross-sectional views for describing electronic devices 78-1 and 78-2 which may be included in an optical device package according to at least one example embodiment.

In detail, various electronic devices (for example, the electronic devices 78-1 and 78-2) may be used for the optical device package according to at least one example embodiment. As illustrated in FIG. 29A, the electronic device 78-1 may include the inner electronic device body 80, an electronic device through via 180, first and second electronic device pads 182 and 186, and first and second electronic device connection terminals 184 and 188.

The first and second electronic device pads 182 and 186 may be arranged below and above the inner electronic device body 80, respectively. The first and second electronic device connection terminals 184 and 188 may be arranged below and above the inner electronic device body 80, respectively. The electronic device through via 180 may pass through a lower surface and an upper surface of the inner electronic device body 80.

As illustrated in FIG. 29B, the electronic device 78-2 may include the inner electronic device body 80, the first electronic device pad 182, and the first electronic device connection terminal 184. The first electronic device pad 182 may be arranged below the inner electronic device body 80. The first electronic device connection terminal 184 may be arranged below the inner electronic device body 80.

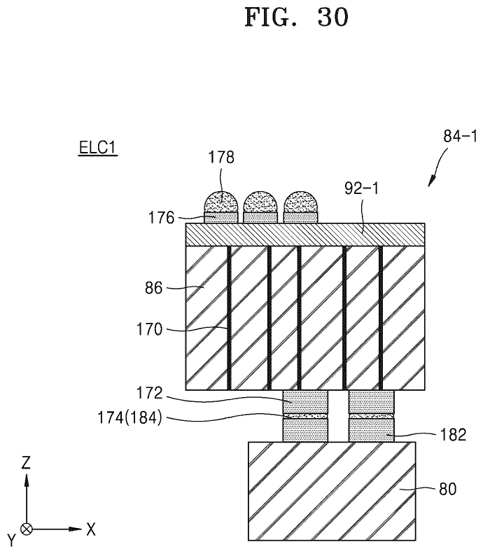

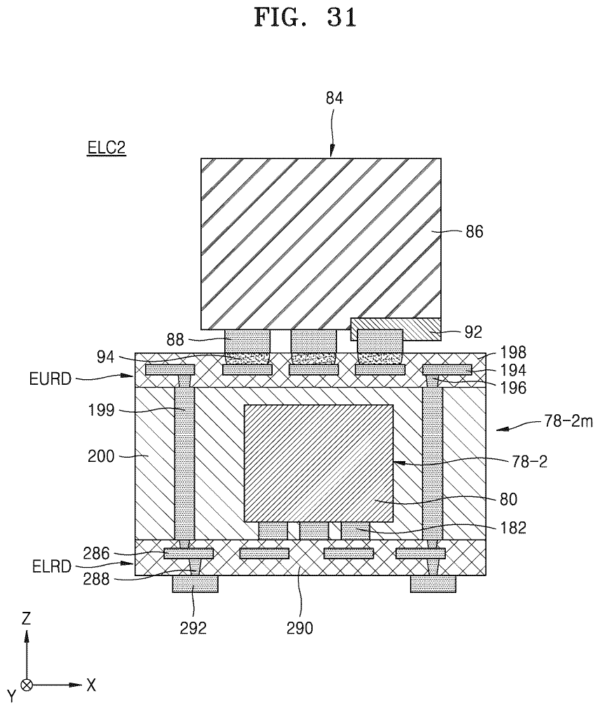

FIG. 30 is a cross-sectional view for describing a coupling relationship between an electronic device and an optical device which may be included in an optical device package according to at least one example embodiment.

In detail, various optical devices (for example, the optical device 84-1) and electronic devices (for example, the electronic device 78-2) may be used for the optical device package according to at least one example embodiment. FIG. 30 illustrates a coupling structure ELC1 of the optical device 84-1 and the electronic device 78-2. The optical device 84-1 is illustrated in FIG. 28A. The optical device 84-1 may include the optical device body 86, the optical device through via 170, the first and second optical device pads 172 and 176, the first and second optical device connection terminals 174 and 178, and the device optical waveguide 92-1.

The electronic device 78-2 is illustrated in of FIG. 29B. The electronic device 78-2 may include the inner electronic device body 80, the first electronic device pad 182, and the first electronic device connection terminal 184. In FIG. 30, the electronic device 78-2 illustrated in FIG. 29B is flipped. The first optical device connection terminal 174 of the optical device 84-1 and the first electronic device connection terminal 184 of the electronic device 78-2 may be connected to each other to form an optical device package.

FIG. 31 is a cross-sectional view for describing a coupling relationship between an electronic device and an optical device which may be included in an optical device package according to at least one example embodiment.

In detail, various optical devices (for example, the optical device 84) and inner electronic device modules (for example, an inner electronic device module 78-2m) may be used for the optical device package according to at least one example embodiment. FIG. 31 illustrates a coupling structure ELC2 of the optical device 84 and the inner electronic device module 78-2m. The optical device 84 may include the optical device body 86 and the device optical waveguide 92. The device optical waveguide 92 may be located below the optical device body 86.

The inner electronic device module 78-2m may include the electronic device 78-2. The electronic device 78-2 may include the inner electronic device body 80 and the first electronic device pad 182. The inner electronic device module 78-2m may include an inner electronic mold layer 200, an electronic mold through via 199, an electronic upper redistribution structure EURD, and an electronic lower redistribution structure ELRD.

The inner electronic mold layer 200 may mold the electronic device 78-2. The electronic mold through via 199 may pass through an upper portion and a lower portion of the inner electronic mold layer 200. The electronic upper redistribution structure EURD may include an electronic upper redistribution layer 194, an electronic upper redistribution via 196, an electronic upper redistribution insulating layer 198, and an electronic upper connection terminal 201.

The electronic lower redistribution structure ELRD may include an electronic lower redistribution layer 286, an electronic lower redistribution via 288, and an electronic lower redistribution insulating layer 290. An electronic lower interconnect pad 292 may be located below the electronic lower redistribution structure ELRD.

While the inventive concepts have been particularly shown and described with reference to example embodiments thereof, it will be understood that various changes in form and details may be made therein without departing from the spirit and scope of the following claims.

What is claimed is:

1. A semiconductor package comprising:
an interposer structure comprising
an interposer body,
an interposer upper interconnect structure above the interposer body,
an interposer lower interconnect structure below the interposer body, and
an interposer through via in the interposer body, the interposer through via electrically connecting the interposer upper interconnect structure to the interposer lower interconnect structure;
an electronic device on the interposer structure, the electronic device electrically connected to the interposer upper interconnect structure;
an electronic mold layer on the electronic device and on the interposer structure; and
an optical device package in contact with the electronic mold layer, on the interposer structure, facing a side of the electronic device, and electrically connected to the interposer upper interconnect structure, the optical device package comprising
a glass substrate, the glass substrate including a substrate optical waveguide,
a substrate redistribution structure below the glass substrate, the substrate redistribution structure electrically connected to the interposer upper interconnect structure,
an optical device on the glass substrate and electrically connected to the substrate redistribution structure, the optical device comprising a device optical waveguide coupled to the substrate optical waveguide, and
an optical mold layer on the glass substrate and on the optical device; and
an optical connector structure on a side of the glass substrate and optically connected to the substrate optical waveguide.

2. The semiconductor package of claim 1, wherein a side surface of the optical mold layer is in contact with a side surface of the electronic mold layer.

3. The semiconductor package of claim 1, further comprising:
an interposer upper pad on the interposer upper interconnect structure,
wherein an electronic device pad of the electronic device is electrically connected to the interposer upper pad.

4. The semiconductor package of claim 1, further comprising:
an interposer upper pad on the interposer upper interconnect structure; and
a substrate redistribution pad below the substrate redistribution structure
wherein the interposer upper pad is electrically connected to the substrate redistribution pad.

5. The semiconductor package of claim 1, further comprising:
a substrate pad on the glass substrate; and
a substrate through via passing through the glass substrate in the glass substrate,
wherein the substrate pad is electrically connected to the substrate redistribution structure through the substrate through via.

6. The semiconductor package of claim 1, further comprising:
a substrate pad is further arranged on the glass substrate,
wherein the optical device further comprises an optical device pad, and
the optical device pad is electrically connected to the substrate pad.

7. The semiconductor package of claim 1, wherein the substrate optical waveguide comprises an ion exchanged optical waveguide formed on the glass substrate.

8. The semiconductor package of claim 1, wherein the substrate optical waveguide is optically connected to the device optical waveguide through an evanescent coupling.

9. A semiconductor package comprising:
an interposer structure comprising
an interposer body,
an interposer upper interconnect structure above the interposer body,
an interposer lower interconnect structure below the interposer body,
and an interposer through via in the interposer body, the interposer through via electrically connecting the interposer upper interconnect structure to the interposer lower interconnect structure;
at least one electronic device on the interposer structure, the at least one electronic device electrically connected to the interposer upper interconnect structure;
an electronic mold layer on the at least one electronic device and on the interposer structure;
an optical device package in contact with the electronic mold layer, on the interposer structure, facing a side of the at least one electronic device, and electrically connected to the interposer upper interconnect structure, the optical device package comprises
a glass substrate,
a cavity lower than an upper surface of the glass substrate,
a substrate optical waveguide on the upper surface of the glass substrate,
an inner electronic device in the cavity,
a substrate redistribution structure below the glass substrate and electrically connected to the interposer upper interconnect structure,
an optical device on the inner electronic device, the optical device electrically connected to the inner electronic device and the substrate redistribution structure, and comprising a device optical waveguide coupled to the substrate optical waveguide, and
an optical mold layer on the glass substrate, on the inner electronic device, and on the optical device; and
an optical connector structure optically connected to the substrate optical waveguide on a side of the glass substrate.

10. The semiconductor package of claim 9, wherein the optical mold layer is on a side surface of the glass substrate, and
a side surface of the optical mold layer is in contact with a side surface of the electronic mold layer.

11. The semiconductor package of claim 9, further comprising:
an optical device bonding pad in the optical device; and
an inner electronic device bonding pad in the inner electronic device,
wherein the optical device bonding pad and the inner electronic device bonding pad are bonded and electrically connected to each other.

12. The semiconductor package of claim 9, further comprising:
a substrate pad on the glass substrate; and
a substrate through via passing through the glass substrate,
wherein the substrate pad is electrically connected to the substrate redistribution structure through the substrate through via.

13. The semiconductor package of claim 9, further comprising:
a substrate pad on the glass substrate;
wherein the optical device further comprises an optical device pad, and
the optical device pad is electrically connected to the substrate pad.

14. The semiconductor package of claim 9, wherein the substrate optical waveguide comprises an ion exchanged optical waveguide formed on the glass substrate.

15. The semiconductor package of claim 9, wherein the substrate optical waveguide overlaps the device optical waveguide and is optically connected to the device optical waveguide through an evanescent coupling.

16. A semiconductor package comprising:
an interposer structure comprising
an interposer body,
an interposer upper interconnect structure above the interposer body,
an interposer lower interconnect structure below the interposer body, and
an interposer through via in the interposer body, the interposer through via connecting the interposer upper interconnect structure to the interposer lower interconnect structure;
at least one bridge device in the interposer body, the at least one bridge device electrically connected to the interposer upper interconnect structure;
at least one electronic device on the interposer structure, the at least one electronic device electrically connected to the interposer upper interconnect structure and the at least one bridge device;
an electronic mold layer on the at least one electronic device and on the interposer structure;
an optical device package in contact with the electronic mold layer, on the interposer structure, on a side of the at least one electronic device, and electrically connected to the at least one electronic device through the interposer upper interconnect structure and the at least one bridge device, the optical device package comprises
a glass substrate,
a cavity lower than an upper surface of the glass substrate,
a substrate optical waveguide on the upper surface of the glass substrate,
an inner electronic device in the cavity,
a substrate redistribution structure below the glass substrate and electrically connected to the interposer upper interconnect structure,
an optical device on the inner electronic device, the optical device electrically connected to the inner electronic device and the substrate redistribution structure, and comprising a device optical waveguide coupled to the substrate optical waveguide, and
an optical mold layer on the glass substrate, the inner electronic device, and the optical device; and
an optical connector structure optically connected to the substrate optical waveguide on a side of the glass substrate.

17. The semiconductor package of claim 16, wherein the at least one bridge device further comprises a bridge device pad, and
the bridge device pad is electrically connected to the interposer upper interconnect structure.

18. The semiconductor package of claim 16, wherein the optical mold layer is on a side surface of the glass substrate, and
a side surface of the optical mold layer is in contact with a side surface of the electronic mold layer.

19. The semiconductor package of claim 16, wherein the optical device further comprises
an optical device pad,
a substrate pad is further on the glass substrate,
a substrate through via passing through the glass substrate is further arranged in the glass substrate, and
wherein the optical device pad is electrically connected to the substrate redistribution structure through the substrate pad and the substrate through via.

20. The semiconductor package of claim 16, wherein
the substrate optical waveguide comprises an ion exchanged optical waveguide formed on the glass substrate,
the substrate optical waveguide overlaps the device optical waveguide, and
the substrate optical waveguide is optically connected to the device optical waveguide through an evanescent coupling.
